(19) United States
(12) Patent Application Publication
(10) Pub. No.: US 2025/0277836 A1
(43) Pub. Date: Sep. 4, 2025

(54) MULTIPATH CROSS CORRELATION RADIOMETRY

(71) Applicant: The Regents of the University of Colorado, a body corporate, Denver, CO (US)

(72) Inventor: ALBIN J. GASIEWSKI, Denver, CO (US)

(21) Appl. No.: 18/858,709

(22) PCT Filed: Apr. 20, 2023
(86) PCT No.: PCT/US2023/066012

§ 371 Date: Oct. 21, 2024

Related U.S. Application Data
(60) Provisional application No. 63/333,024, filed on Apr. 20, 2022.

(51) Int. Cl. G01R 29/08; G01R 35/00

(52) U.S. Cl. CPC G01R 29/0871; G01R 35/005

(57) ABSTRACT

The described technology provides a radiometer system, including an N-path transmission combiner including one or more sum-difference couplers and one or more quadrature couplers to generate N-path output signals including one or more sum output signals, difference output signals, and quadrature injected noise reference output signals; and, an N-path radio receiver array configured to couple the one or more sum output signals, the difference output signals, and the quadrature injected noise reference output signals into a complex cross-correlator, wherein the complex cross-correlator is configured to process the one or more sum output signals, the difference output signals, and the quadrature injected noise reference output signals to generate a plurality of calibration outputs to be interpreted by a computer based algorithm to determine calibration parameters of the radiometer system.

### CROSS REFERENCE TO RELATED APPLICATIONS

This application is a Patent Cooperation Treaty (PCT) application based on and claims benefit of priority to U.S. provisional patent application No. 63/333,024 filed Apr. 20, 2022, and entitled MULTIPATH CROSS CORRELATION RADIOMETRY which is incorporated herein by reference in its entirety.

### BACKGROUND

Radiometry relates to giving precise measure of microwave power over a wide range of frequencies, from 100 KHz to various THz. It is very difficult to calibrate power meters used in measuring power below a percent or so in accuracy. However, various weather sensors and environment sensors require techniques that can provide much more precise calibration. However, such precise calibration requires complex external or internal calibration hardware and is subject to drift and uncertainties. In addition, precise calibration can be compromised by large out-of-band received signals caused by radio interference which reduce the sensitivity of radiometer amplifiers.

### SUMMARY

The described technology provides a radiometer system, including an N-path transmission combiner including one or more sum-difference couplers and one or more quadrature couplers to generate N-path output signals including one or more sum output signals, difference output signals, and quadrature injected noise reference output signals; and, an N-path radio receiver array configured to couple the one or more sum output signals, the difference output signals, and the quadrature injected noise reference output signals into a complex cross-correlator, wherein the complex cross-correlator is configured to process the one or more sum output signals, the difference output signals, and the quadrature injected noise reference output signals to generate a plurality of calibration outputs to be interpreted by a computer based algorithm to precisely determine calibration parameters of the radiometer system. This precise determination is possible even if the receiver amplifier gains are compromised by large out-of-band radio interference signals.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

FIG. 1 illustrates an example multipath cross-correlating radiometer system that is configured to provide a quadrature-injected constant noise reference required for a phase reference “self-calibration” capacity.

FIG. 2 illustrates an alternative example implementation of a radiometer system, also referred to as a 2QS radiometer system.

FIG. 3 illustrates an alternative example implementation of a 2QS radiometer system with alternative permutations of quad couplers.

FIG. 4 illustrates an alternative implementation of a radiometer system where the position of the quad coupler and the sum-difference coupler are reversed.

FIG. 5 illustrates an example graph explaining the functioning of the illustrated radiometer system's complex cross correlation.

FIG. 6 illustrates an alternative example graph depicting a calibration solution using 2 SQ implementation disclosed above in FIG. 4.

FIG. 7 illustrates an example graph with results of monte carlo simulation illustrating the functioning of the 2SQ2 radiometer calibration system disclosed herein.

FIG. 8 illustrates alternative example implementations of a calibration source which may be used in a 2QS radiometer calibration system disclosed herein.

FIG. 9 illustrates an example 2QS system 900 where the sum-difference coupler is replaced by a Wilkinson divider.

FIG. 10 illustrates an example implementation of a 2-path lobe difference analog correlation radiometer using the radiometer calibration system disclosed herein.

FIG. 11 illustrates an alternative example implementation of a self-calibrating 2-path lobe difference analog correlation radiometer using the radiometer calibration system disclosed herein.

FIG. 12 illustrates an example three-path digital correlating radiometer 3SCC.

FIG. 13 illustrates an alternative example rendition of the three-path digital correlating radiometer 3SCC disclosed in FIG. 12.

FIG. 14 illustrates an example implementation of a 3-path 3SCC combiner.

FIG. 15 illustrates an example 4-path 4QQQQS digital correlating radiometer.

FIG. 16 illustrates an example 4-path 4SSQS digital correlating radiometer.

FIG. 17 illustrates an example 4-path 4SQQS digital correlating radiometer.

FIG. 18 illustrates an example 4-path 4SQQQ digital correlating radiometer.

FIG. 19 illustrates an example 4-path 4SQQQ implementation for L-Band (1-2 GHz).

FIG. 20 illustrates an example 4-Path 4QQDQQ Digital Correlating Radiometer.

FIG. 21 illustrates an example 4-Path 2-4SQQQ digital correlating polarimeter.

FIG. 22 illustrates an example alternate implementation of 4-Path 2-4SQQQ digital correlating polarimeter.

FIG. 23 illustrates an example 6-path phase-calibrating digital correlating polarimeter.

FIG. 24 illustrates an example 8-path phase-calibrating digital correlating polarimeter.

FIG. 25 illustrates an alternative 8-path phase-calibrating digital correlating polarimeter.

FIG. 26 illustrates an alternative 4-path phase-calibrating digital correlating polarimeter.

FIG. 27 illustrates an example computing device for implementing the features and operations of the described technology.

### DETAILED DESCRIPTIONS

The technology disclosed herein includes a multipath cross-correlation radiometry (MXCR) method for calibrating radiometers using multiple radio paths and digital cross-correlation to provide an inherently precise and stable calibration of radiometers without requiring any external calibration. The MXCR disclosed herein provides a means for achieving near-fundamental radiometer precision without the need for observing external calibration targets or using internal calibration switching. As a result, the MXCR disclosed herein reduces the cost, mass, and size of radiometers, polarimeters, and spectrometers, and permits laboratory spectrum analysis with up to tens of thousands of times improved absolute accuracy relative to current commercial spectrum analyzers. Specifically, the MXCR disclosed herein provides a means for high precision measurement of electromagnetic signal power using a correlation-based radiometric detection method that dispenses with the need for external calibration references or internal calibration switching. The methodology can be used for radiometers used for measuring energy up to tens of THz.

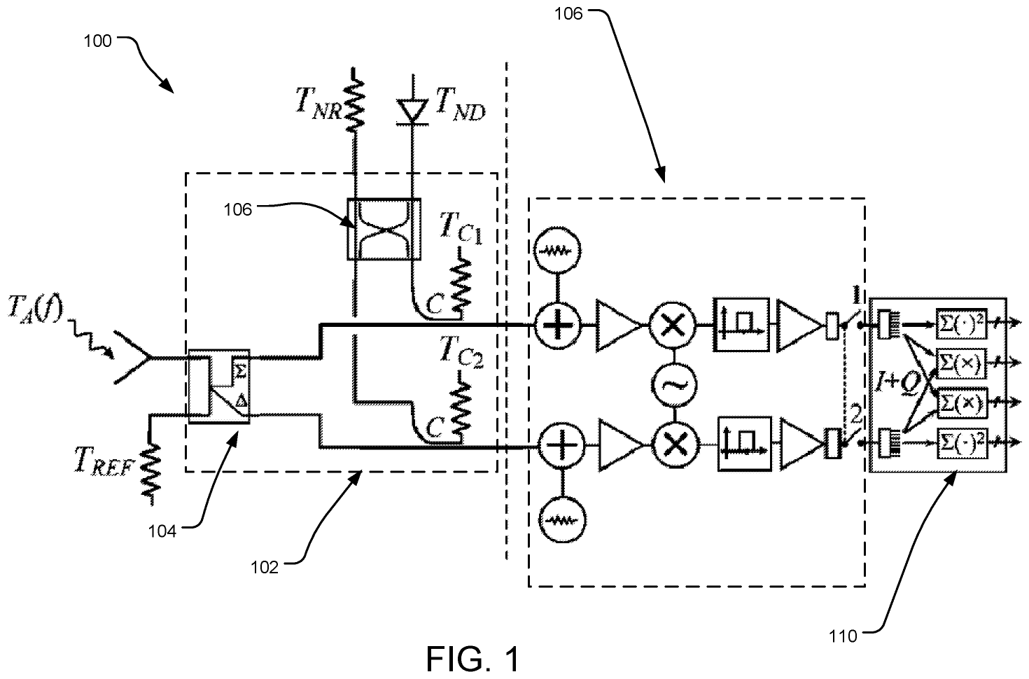

FIG. 1 illustrates a multipath cross-correlating radiometer system 100 that is configured to provide quadrature-injected constant noise reference required for a phase reference “self-calibration” capacity. Here the coupling C can be reduced to provide nearly full radiometric efficiency.

The radiometer system 100 includes a combiner 102 including a sum-difference coupler 104 configured to receive in an input antenna T_{A}(f) signal and a reference signal T_{REF} and generate a sum output signal and a difference output signal. The combiner 102 may be an N-path transmission combiner 102. A quadrature coupler 106 couples in a noise reference TNR signal and a noise diode TND signal to generate a quadrature injected noise reference output signal. Specifically, the outputs of the combiner 102 may include an upper output signal 112 that is a combination of sum output signals and quadrature injected noise reference output signals and a lower output signal 114 that is a combination of difference output signals and the quadrature injected noise reference output signals.

An N-path (multipath) radio receiver array 108 couples the sum output signal, the difference output signal, and the quadrature injected noise reference output signal into a complex cross-correlator 110. The N-path radio receiver array 108 may also be referred to as an N-path coherent radio receiver array 108 or as an N-path homodyne radio receiver array 108.

In one implementation, the complex cross-correlator 110 is configured to process the sum output signal, the difference output signal, and the quadrature injected noise reference output signal to generate a plurality of calibration outputs to be interpreted by a computer based algorithm to determine calibration parameters of the radiometer system 100. Specifically, the complex correlator 110 generates the calibration outputs based on complex correlation between an in-phase part I and a quadrature phase part Q. The radiometer system 100 may also be referred to as 2SQ radiometer system as it uses a two (2) path signal using a sum-difference coupler 104 and the quadrature coupler 106. The complex cross-correlator 110 may be implemented using either analog-to-digital sampling and digital cross-correlation or analog multiplication or squaring and analog cross-correlation. In some implementations, the number of bits for the analog-to-digital conversion performed by the analog-to-digital sampling may be as few as one binary digit.

Alternatively, the number of bits of digital sampling precision can vary among the receiver paths across complex cross-correlator 110. Yet alternatively, the receivers can be of varying type and quality among the receiver paths such that the number of ADD converters across various paths of the complex cross-correlator 110 may be different for each path. Similarly, the receiver paths, specifically the path from left of radio receiver array 108 to the summers in the complex cross-correlator 110, can be spatially separated by arbitrarily large distances and they are coherently clocked. In an implementation, the digital sampling receivers may be used to detect radio frequency interference using fourth order (i.e., statistical kurtosis) or higher order moment products of the sampled signals.

In one implementation, the complex cross-correlator 110 is configured to perform complex cross-correlation using radio frequency (RF) optical modulators and optical photonic correlators. The optical photonic correlators may be, for example, photonic crystals or combination of photonic combiners and optical detectors. In an alternative implantation, the optical photonic correlators may be configured to perform the functions of the complex cross-correlator 110 and generate a number of complex correlator products that may be used for further processing. In an alternative implementation, the complex cross-correlator 110 performs the complex cross-correlation using analog multiplying mixers or analog pseudo-correlating diode detectors.

In an alternative implementation, the complex cross-correlator 110 may perform complex cross-correlation using coherent digital sampling that is implemented using coherently synchronized software defined radios (SDRs). For example, the SDRs may be coherently synchronized using a common oscillator that is either connected to each of the SDRs by a cable, a waveguide, or an optical fiber. Alternatively, the complex cross-correlator 110 may transmit to the SDRs from a common radio source.

An implementation of the radiometer 100 may be used as a receiver front end for a communication system or radar wherein cross-correlation is used to estimate the gain and receiver noise temperature of the receiver to compensate for variations in these quantities due to either (i) variations that are environmentally-forced through (for example) temperature, humidity, vibration, etc., (ii) variations caused by radio interference that would change this gain through either compression or nonlinear modulation, or (iii) variations that are caused by use of an automatic gain control feedback mechanism.

Furthermore, in an implementation of the radiometer 100, the in-phase (I) and quadrature (Q) signals are obtained by Fourier transformation of digitally sampled signals. Alternatively, the in-phase (I) and quadrature (Q) signals are obtained by Hilbert transformation of digitally sampled signals. Yet alternatively, the in-phase (I) and quadrature (Q) signals are obtained by filtering of digitally sampled signals. Alternatively, the in-phase (I) and quadrature (Q) signals are obtained by mixer down conversion using a quadrature phase I/Q mixer.

In an alternative implementation of the radiometer 100, the in-phase (I) and quadrature (Q) signals are obtained by mixer down conversion using a quadrature phase I/Q mixer and analog signal cross-correlation using detector diodes. Alternatively, the in-phase (I) and quadrature (Q) signals are obtained by mixer down conversion using a quadrature phase I/Q mixer and analog signal cross-correlation using analog signal multiplier circuits. Alternatively, the n-phase (I) and quadrature (Q) signals are obtained by mixer down conversion using a quadrature phase I/Q mixer and analog signal cross-correlation using analog mixers.

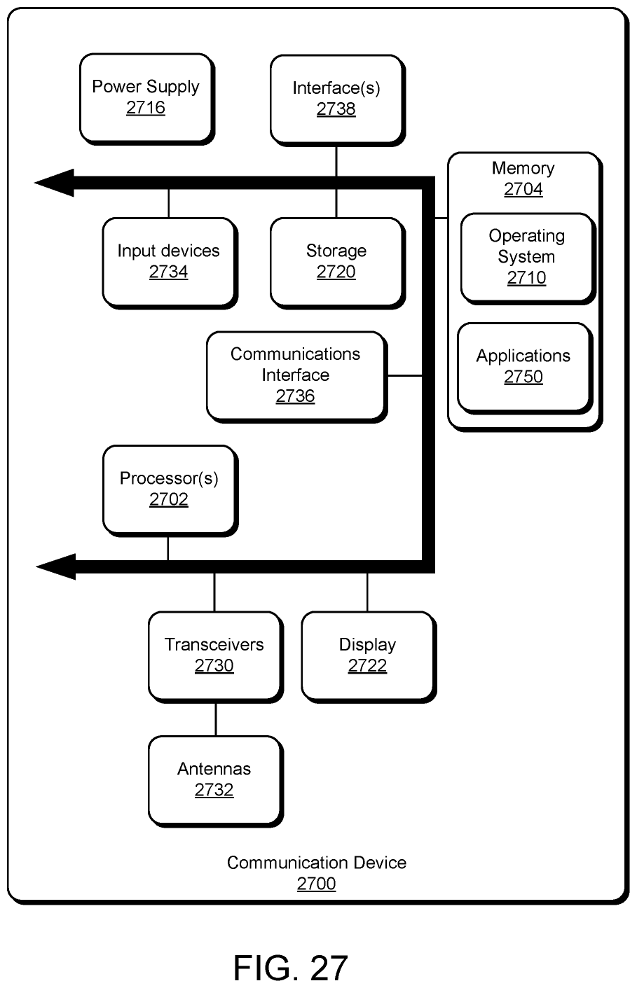

In an alternative implementation, feedback nulling may be used to change one or more reference temperature input signals T_{REF} into the sum-difference coupler 104, one or more receiver filter parameters or amplifier gain values, or one or more analog-to-digital converter range or precision settings using the computed input temperature value. An example of such input signal is given in further detail below in FIG. 27. In an example implementation, the down conversion section 118 in the radio receiver array 108 may be optional and the digital sampling and cross-correlation of signals is performed directly for each path after the transmission network without the use of down conversion.

In an alternative implementation of the radiometer 100, the inputs T_{A}(f) may be sensor ports on a laboratory instrument used to analyze signal power and/or measure the signal spectrum. In an alternative implementation of the radiometer 100, the sampling of signals is performed after one, two, or any number of successive stages 118 of coherent down conversion. Specifically, successive stages of down conversion 118 may be used, for example, to reduce the signal bandwidth to be small enough to be able to be digitally sampled and cross-correlated.

In another implementation of the radiometer 100 with single or multiple antenna inputs, three or more receiver paths (N-path) may be used to accomplish single-beam single-polarization radiometric measurements with only a single calibration state, wherein a calibration state may be defined as to be any single observations made using the radiometer. Furthermore, the radiometer 100 may be used as an internally self-calibrating interferometer with two or more of input antennas and a number of receivers paths (N-path) greater than or equal to three to accomplish directional beam temperature differencing using two antenna beams, or polarization differencing using a dual-polarized antenna, with only a single calibration state.

In an alternative implementation of the radiometer 100 may use a predetermined number Na beams or polarizations and the number of receivers paths (N-path) greater than or equal 1.5+0.5*sqrt(5+4*Na) receivers to accomplish multiple-beam directional and/or multiple-polarization differencing with only a single calibration state. Such an implementation allows synthesizing multiple beams to implement a push-broom radiometer.

Implementations of the radiometer 100 may also be used as the radio digital front end of an element of an interferometer or digital beam forming receiver to provide an estimate of the gain and receiver noise temperature of the element. Alternatively, the radiometer 100 may also be used as the radio digital front end of an element of an interferometer or digital beam forming receiver to provide an estimate of the gain and receiver noise temperature of the element as a means to compensate for radio interference that would either compress, or nonlinearly modulate this gain.

Alternatively, the radiometer 100 may also be used as the radio digital front end of an element of an interferometer or digital beam forming receiver wherein cross-correlation is used to estimate the gain of the element as a means to compensate for radio interference by changing this gain through use of an automatic gain control feedback mechanism.

The implementations of the radiometer, such as the radiometer 100 disclosed herein provides a number of advantages including Internal absolute radiometer calibration without use of external blackbody targets and with single calibration state, suppression of and/or correction for gain compression effects that adversely affect radiometers caused by out-of-band radio frequency interference, independent determination of receiver noise temperature, gain, and relative phase delay of each radiometer amplifier, down conversion, and digital detection path, and absolute calibration while rejecting amplifier gain and receiver noise temperature variations with frequency, temperature, component aging, power supply fluctuations, and electromagnetic interference.

However, compared to other Dicke comparison radiometer, the disclosed implementations may have slightly higher than theoretical lowest receiver sensitivity by a factor of 1/sqrt(2), additional power required to operate additional amplifiers, down converters, digital samplers, and cross-correlators, and additional radio frequency hardware to realize amplifiers, down converters, digital samplers, and cross-correlators.

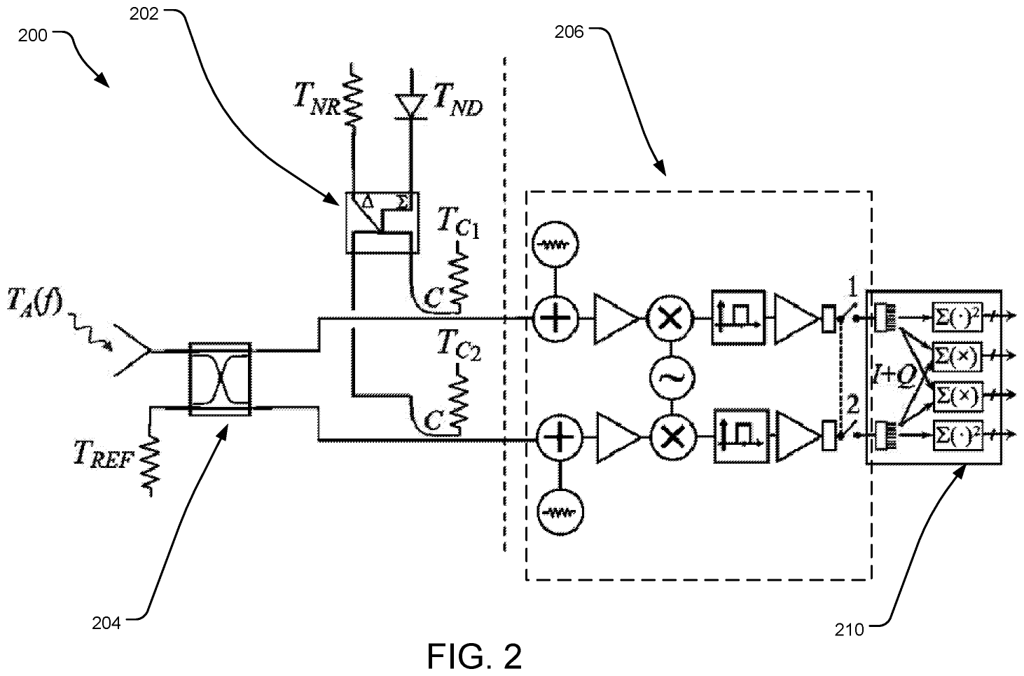

FIG. 2 illustrates an alternative implementation of a radiometer system 200, also referred to as a 2QS radiometer system. Specifically, in the radiometer system 200 a quadrature coupler 202 is configured to receive in an input antenna T_{A}(f) signal and a reference signal T_{REF} and generate a sum output signal and a difference output signal. On the other hand, a sum-difference coupler 204 is configured to couple in a noise reference TNR signal and a noise diode TND signal to generate a quadrature injected noise reference output signal. An N-path (multipath) radio receiver 206 couples the sum output signal, the difference output signal, and the quadrature injected noise reference output signal into a complex cross-correlator 210.

In one implementation, the complex cross-correlator 210 is configured to process the sum output signal, the difference output signal, and the quadrature injected noise reference output signal to generate a plurality of calibration outputs to be interpreted by a computer based algorithm to determine calibration parameters of the radiometer system 100. Specifically, the complex correlator 210 generates the calibration outputs based on complex correlation between an in-phase part I and a quadrature phase part Q.

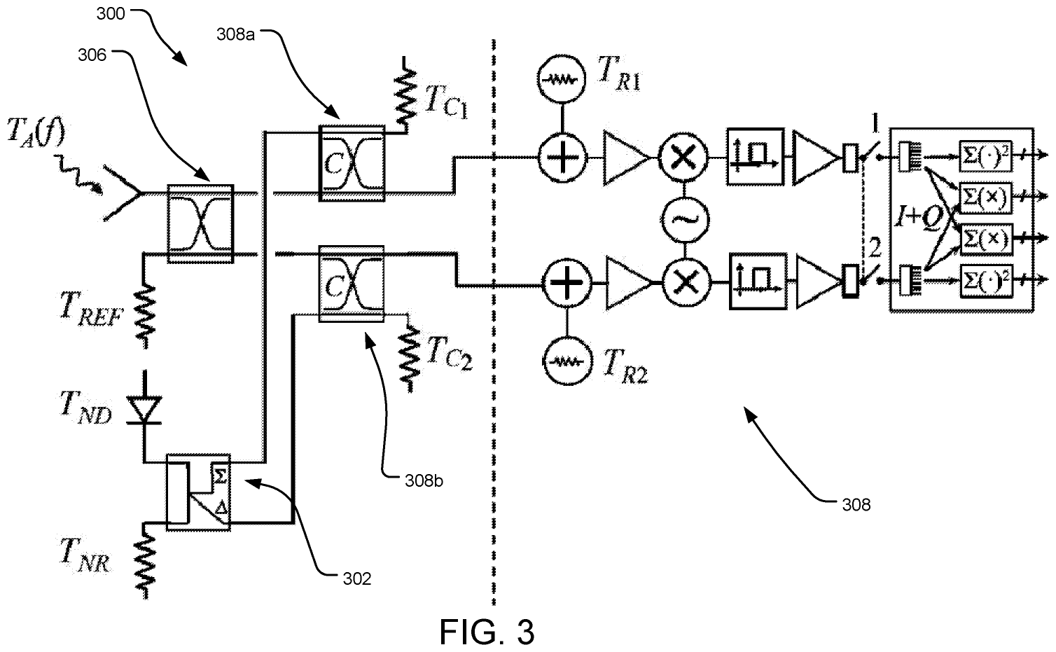

FIG. 3 illustrates an alternative implementation of a 2QS radiometer system 300 with alternative permutations of quad couplers. Specifically, the 2QS radiometer system 300 includes additional quad couplers 308a and 308b that receives the output from a quad coupler 306. The 2QS radiometer system 300 uses a fixed and stable 8-port network with coupling from noise diode source that provides nearly fully efficient use of antenna and reference signals. The 8-ports include two input ports to the quad coupler 306, two inputs to the sum-difference coupler 302, two outputs TC1 and TC2, and two inputs to the radio receiver 308.

Such an implementation allows the gain product and T_{A} to be independently estimated from the real and imaginary part of the complex cross-correlation product provided that the gain phase angle difference is known. This phase difference may be estimated using the correlation measured with the noise diode (ND) and noise reference (NR) swapped. The 8-port architecture can also be referred to as multi-port radio transmission combiner, which allows reference signals to be combined with each other to permit calibration of the radiometer.

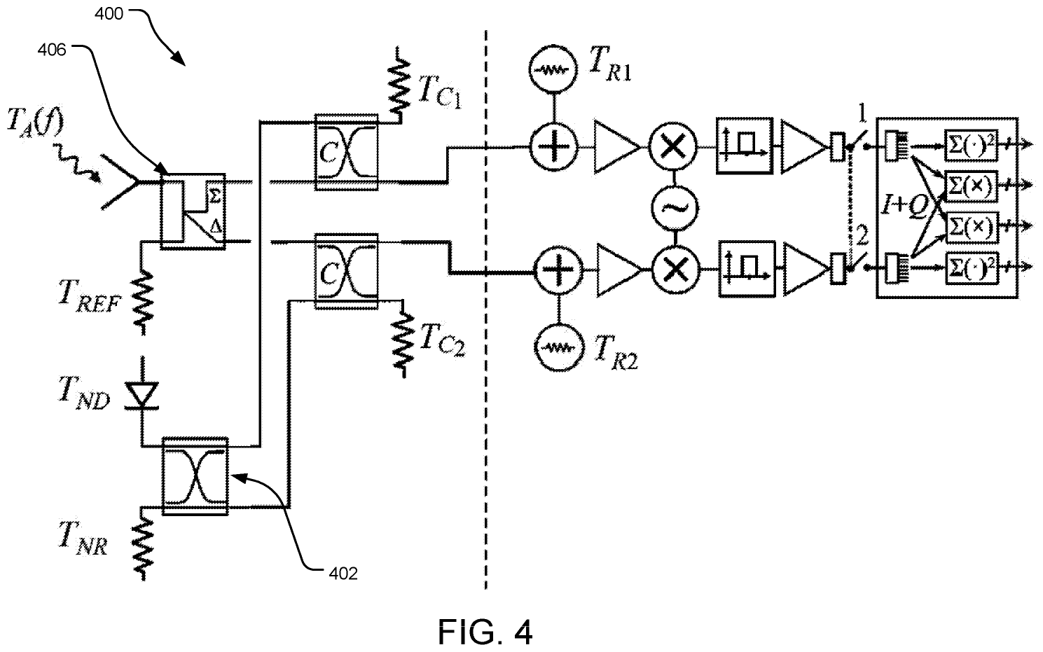

FIG. 4 illustrates an alternative implementation of a radiometer system 400 where the position of the quad coupler 402 and the sum-difference coupler 406 are reversed as compared to that illustrated in the implementation of the radiometer system 300.

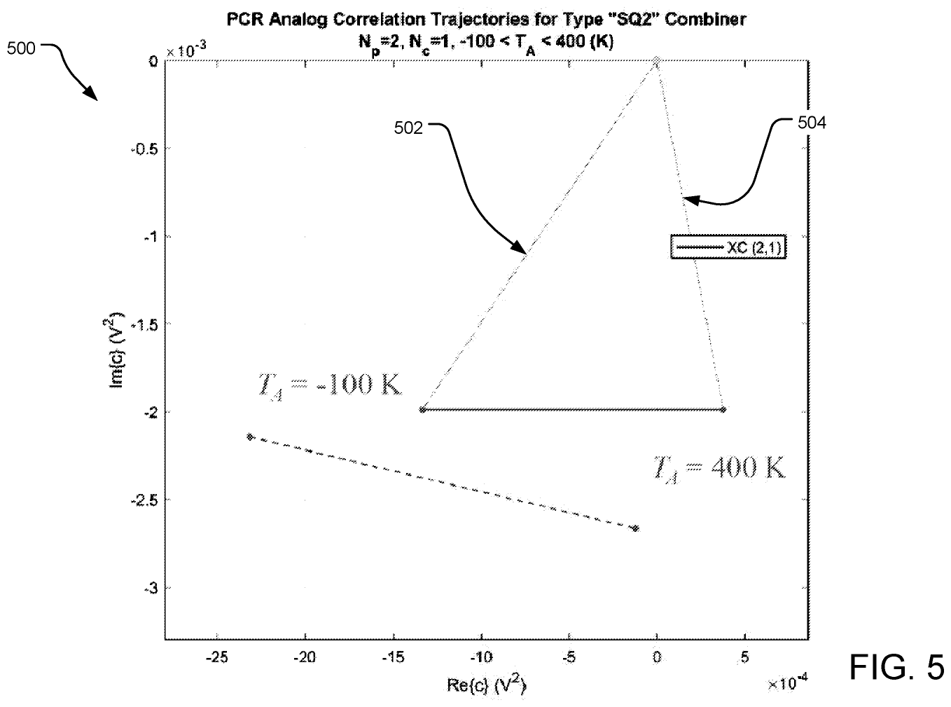

FIG. 5 illustrates a graph 500 explaining the functioning of the illustrated radiometer system's complex cross correlation. Specifically the graph 500 illustrates complex correlation space including a real part and the imaginary part wherein the complex value of the correlation can be used to determine the exact value of T_{A}. using the T_{REF} and the information from the transmission combiner. The line 502 illustrates that as the antenna temperature changes from −100 to 400 degree Kelvin how if the T_{A} changes, the cross-correlation product, which is a complex number, changes as well. In other words, XC (2,1) 504, which is a cross-correlation product between paths 2 and 1, changes as the T_{A} changes. The downward shift of XC (2,1) 504 depends on TND and TNR and provides scale reference for calibrating T_{A}.

Thus, the graph 500 illustrates that the cross correlation provides two real measurements. Proper design of the combiner projects the reference noise power onto a straight line trajectory that is orthogonal to that of the input signal power trajectory. Path gain and phase difference fluctuations rotate and scale the correlation coefficient trajectory, but do not change the orthogonal relationship between the antenna input signal and noise reference components. The combiner imposes this orthogonality, and is a highly stable hardware component.

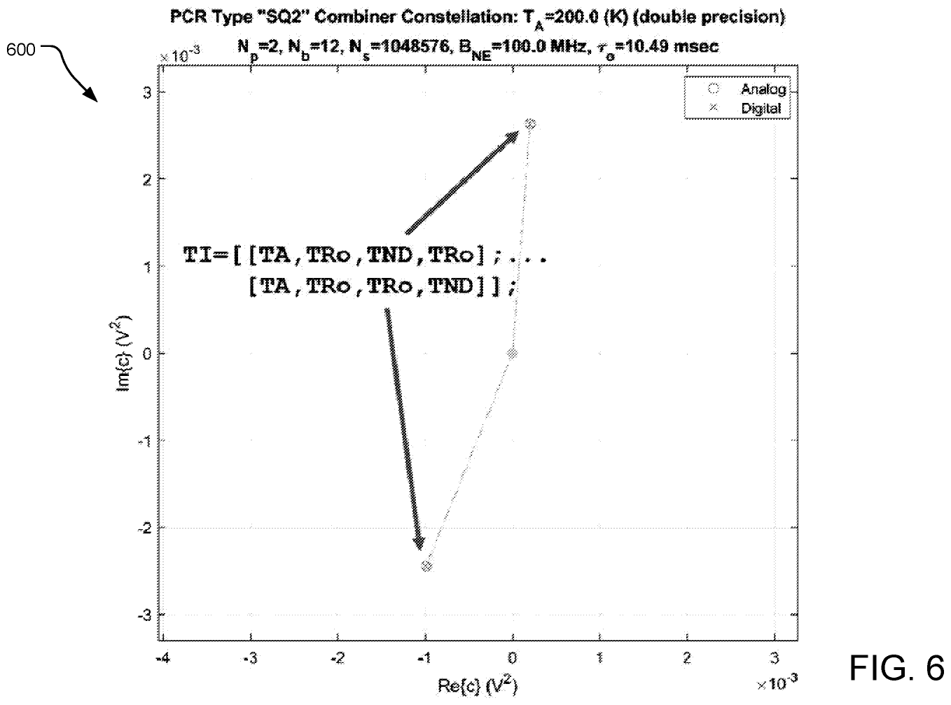

FIG. 6 illustrates an alternative graph 600 depicting a calibration solution using 2 SQ implementation disclosed above in FIG. 4. Specifically, FIG. 6 illustrates constellation of complex correlation values on complex correlation space including a real part on x-axis and the imaginary part on the y-axis. Swapping the TND and TNR sources provide determination of the unknown rotation due to phase difference fluctuations and thus the orthogonal scale factor.

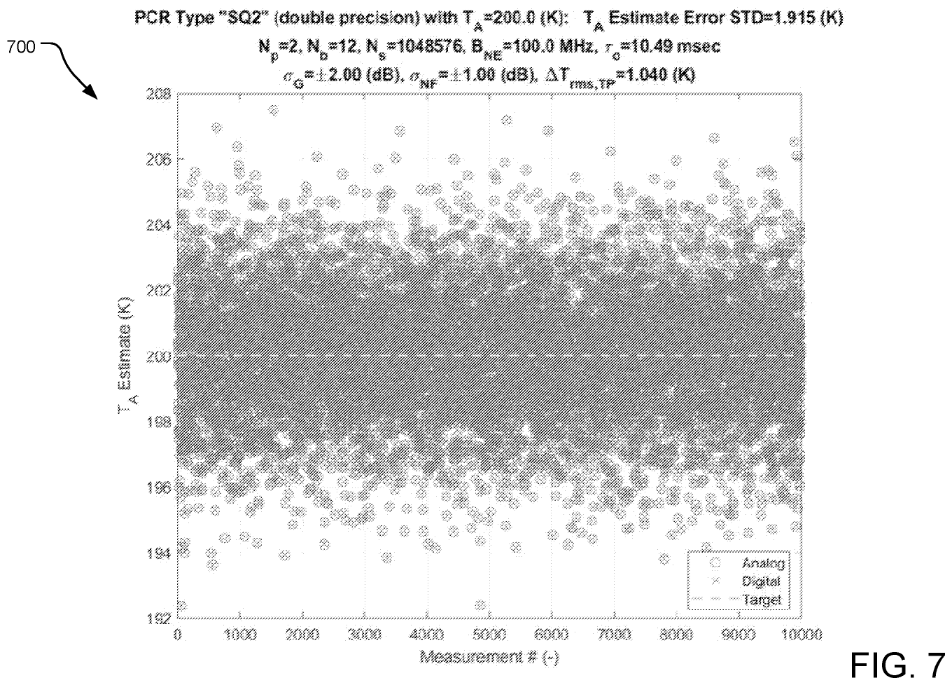

FIG. 7 illustrates a graph 700 with results of monte carlo simulation illustrating the functioning of the 2SQ2 radiometer calibration system disclosed herein. Specifically, the graph 700 depicts cross correlation products for pseudo randomly digitized data with x-axis having sample numbers and y-axis showing the actual estimate of T_{A}.

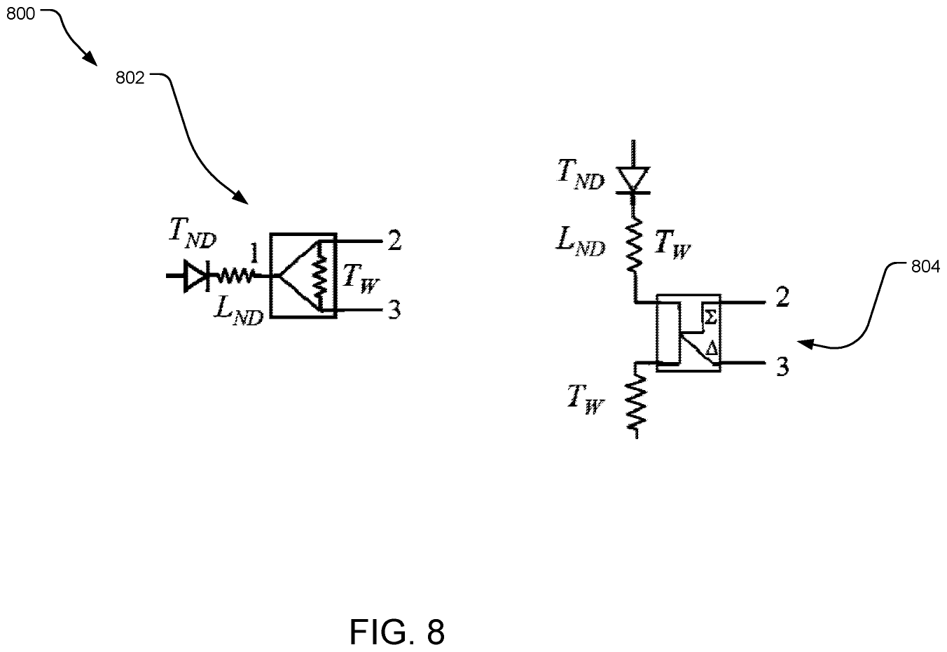

FIG. 8 illustrates alternative implementations of calibration source which may be a Wilkinson divider 802 or a sum-difference coupler 804. Specifically, the Wilkinson divider 802 or the sum-difference coupler 804 may be used to implement the sum-difference coupler of the 2QS radiometer calibration system disclosed above.

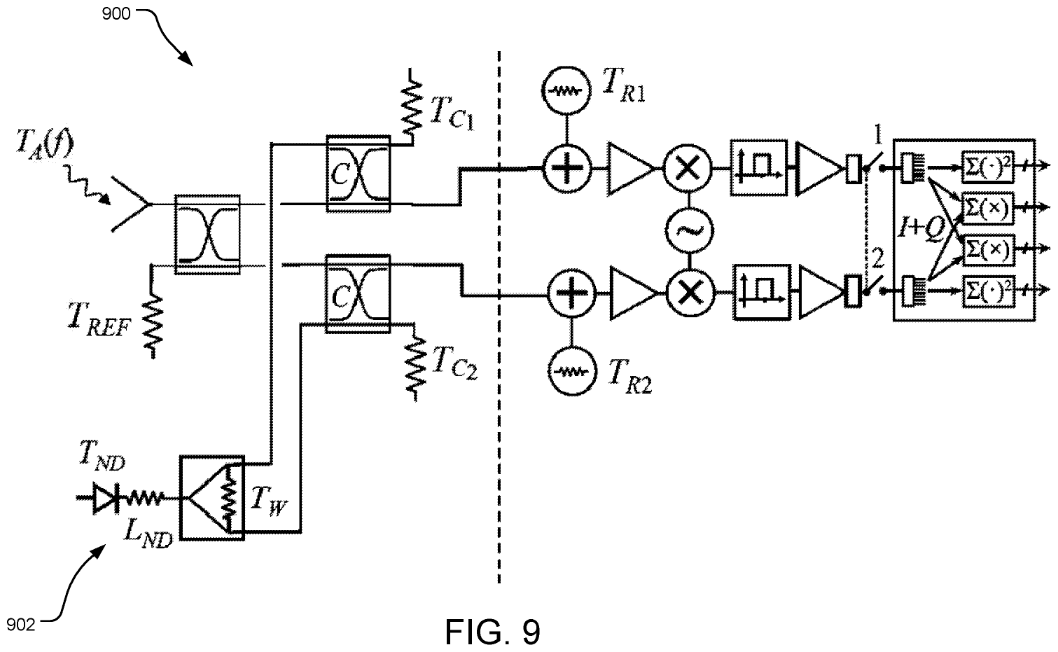

FIG. 9 illustrates the 2QS system 900 where the sum-difference coupler is replaced by a Wilkinson divider 902. Specifically, the 2QS system 900 is an implementation using a fixed and stable 8-port network with coupling from noise diode source that provides nearly fully efficient use of antenna and reference signals. This implementation permits the gain product and T_{A} to be independently estimated from the complex cross-correlation product provided that the path phase angle difference is known. This difference can be estimated using measurements with TND attenuated, but an ambiguity occurs for T_{A}˜T_{REF} if the noise diode is turned completely off.

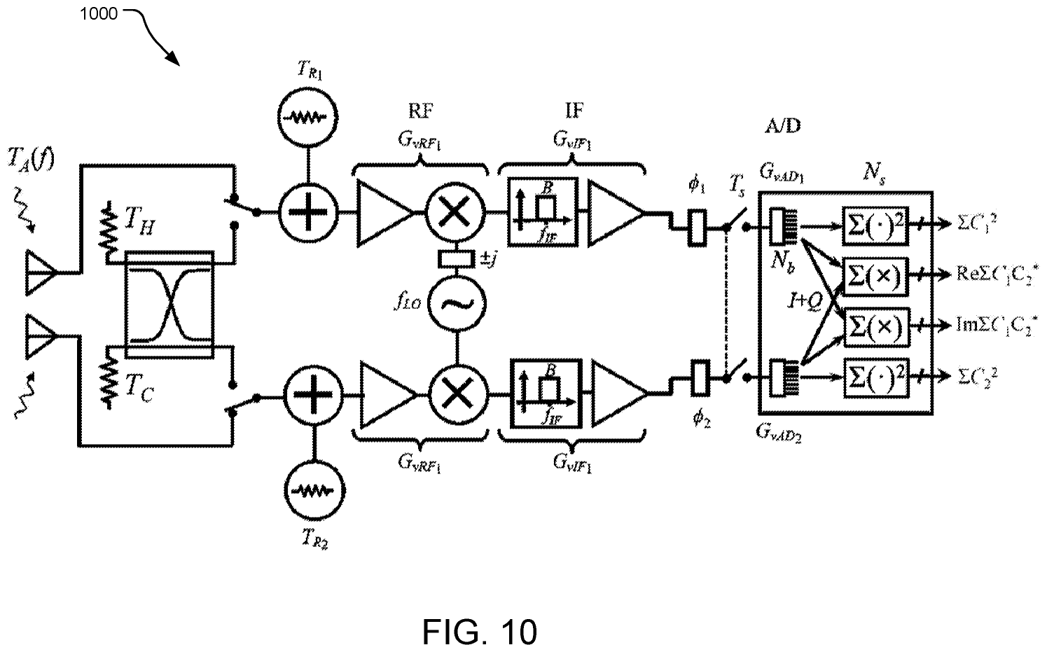

FIG. 10 illustrates an implementation of a 2-path lobe difference digital correlation radiometer (LD2CR) 1000 that shows an application of the radiometer calibration system disclosed herein but with internal calibration switches. The LD2CR 1000 provides both in-phase and quadrature correlation detection necessary for phase reference calibration.

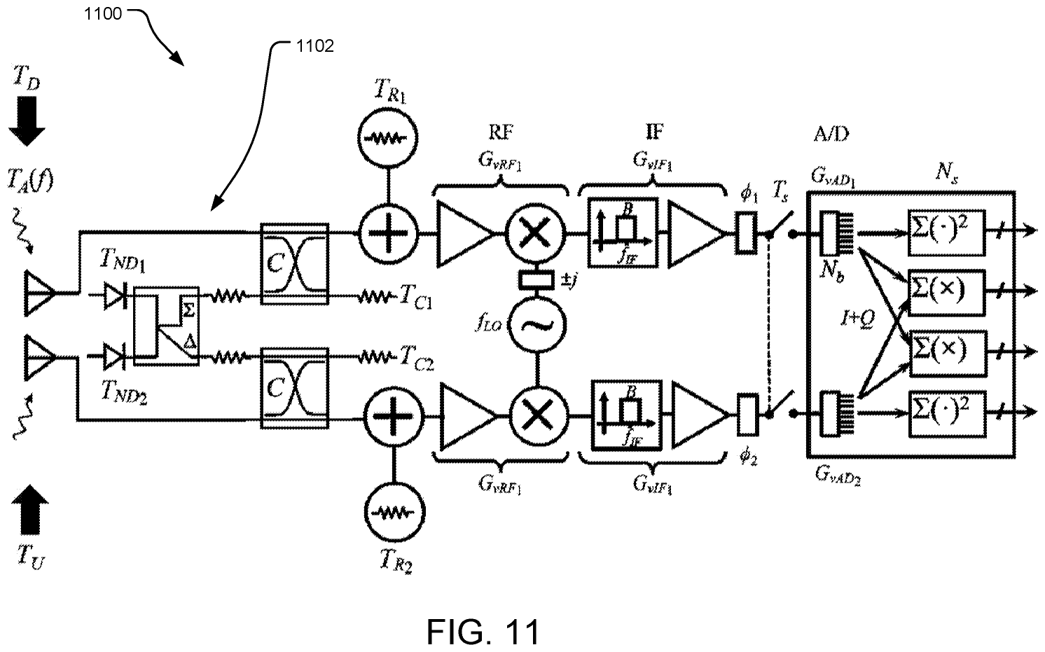

FIG. 11 illustrates a self calibrating 2-path lobe difference digital correlation radiometer (LD2CR) 1100 without the need for internal calibration switches. Specifically, the implementation LD2CR 1100 includes a multipath transmission combiner (MXCR) 1102 at the front end. The noise diodes T_{ND1} and T_{ND2} may be, for example, NS301 SMD (SOD-0323) diodes.

The LD2CR 1100 provides a nearly radiometric efficient SQ2 configuration that can be implemented from LDCR RevC2 by substitution of ΣΔ hybrid and replacement of PIN switches with QH, ΣΔ coupler pairs with small coupling coefficient C (˜ENRND-3 dB) and terminations TC1,2. Resistive couplers with small C could even be used. Path gain phase error Δϕ₂₁ is determined by swapping bias power between ND1 and ND2.

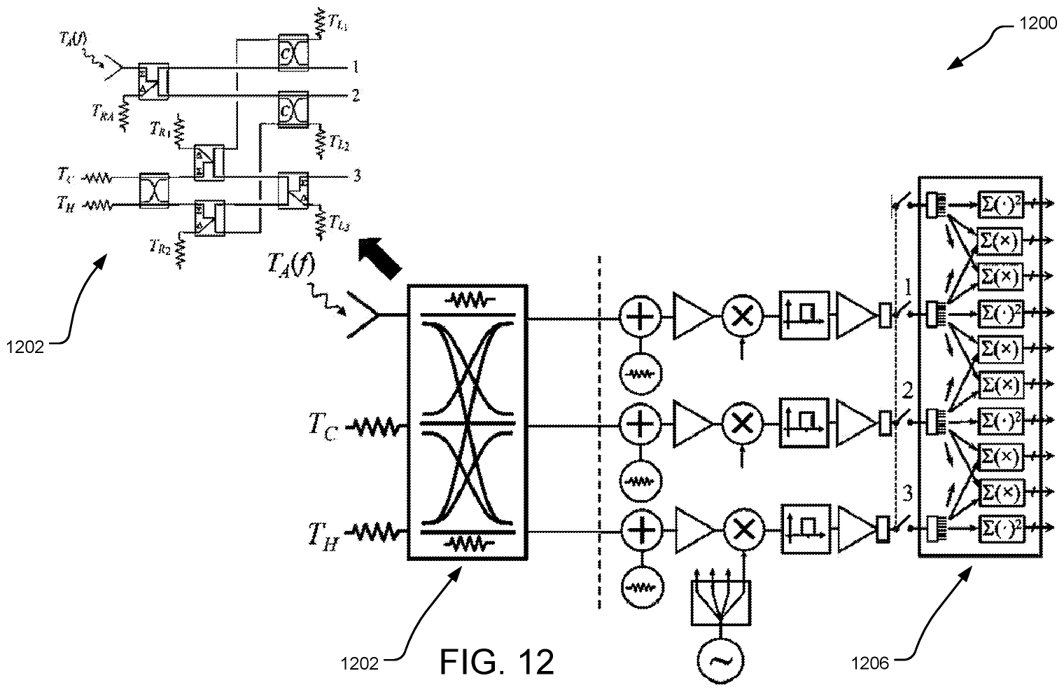

FIG. 12 illustrates that the radiometer calibration systems disclosed herein is not limited to just two paths. Specifically, FIG. 12 illustrates a three-path digital correlating radiometer 3SCC 1200. The three-path digital correlating radiometer 3SCC 1200 is fully signal efficient in that is uses three complex linear correlation equations, thus allowing to solve for up to six unknowns. Here T_{C} and T_{H} used by the transmission combiner 1202 are cold and hot reference temperatures. Similarly, the T_{L1}, T_{L2}, and T_{L3} are also reference temperatures. The reference temperatures are able to be precisely measured using, for example, commonly available thermistors, resistance temperature detectors, or thermocouples.

As shown therein, the three-path digital correlating radiometer 3SCC 1200 uses three cross-correlators 1206. Specifically, if the number of paths is N (three in this implementation), the number of cross correlators may be given by N*(N−1)/2, which results in three cross correlators 1206 in the present implementation. Here, using the third path provides additional correlated signal phase measurements needed to identify the unknown path phase delay differences. All path gains and receiver temperatures can also be estimated once T_{A} is known.

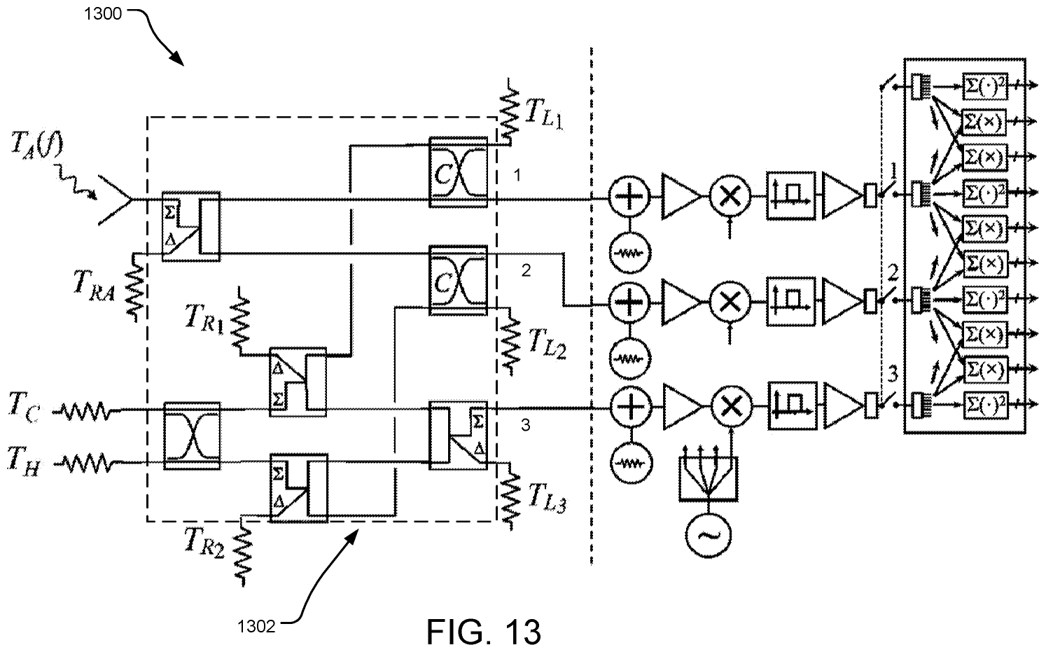

FIG. 13 illustrates an alternative rendition 1300 of the three-path digital correlating radiometer 3SCC disclosed in FIG. 12. Specifically, as shown herein, T_{C} and T_{H} used by the transmission combiner 1302 are cold and hot reference temperatures. Similarly, the T_{L1}, T_{L2}, and T_{L3} are also reference temperatures used by the transmission combiner 1302 but are less impactful if the couplers are of high quality reflectionless design.

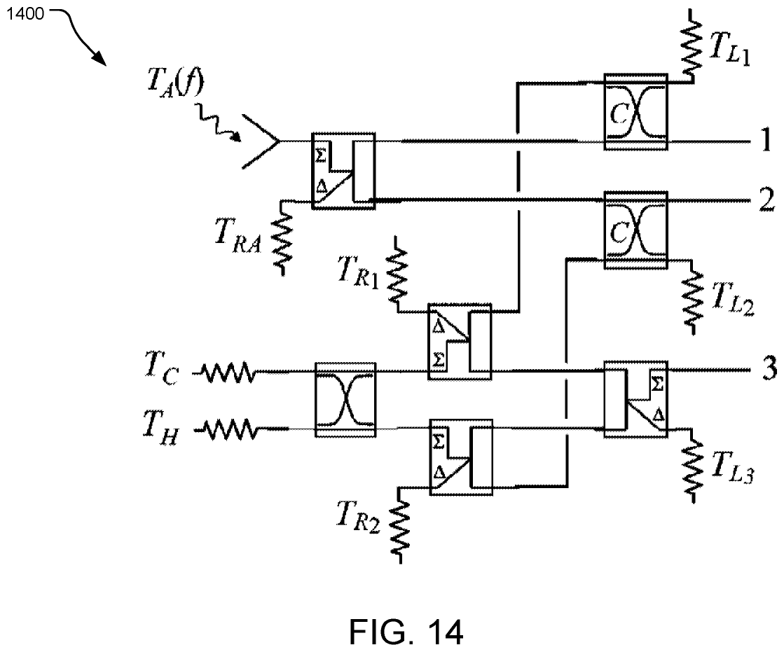

FIG. 14 illustrates an implementation of a 3-path 3SCC combiner 1400. Specifically, the 3-path 3SCC combiner 1400 is a nearly signal efficient combiner where adjustment of the coupling constant C can be used to arbitrarily reduce signal path loss. For example, C=−13 dB results in an efficiency of η_{rad}=95%. Reduced calibration noise power for small coupling values can be compensated by using noise diodes for reference sources (up to 20-35 dB excess noise ratio, or ENR). Noise from load terminations TL1-TL3 is dissipated into input terminations or radiated from the antenna, and thus is largely inconsequential. Output ports are reflectionless to preclude noise emitted from the receiver inputs from entering the signal chain.

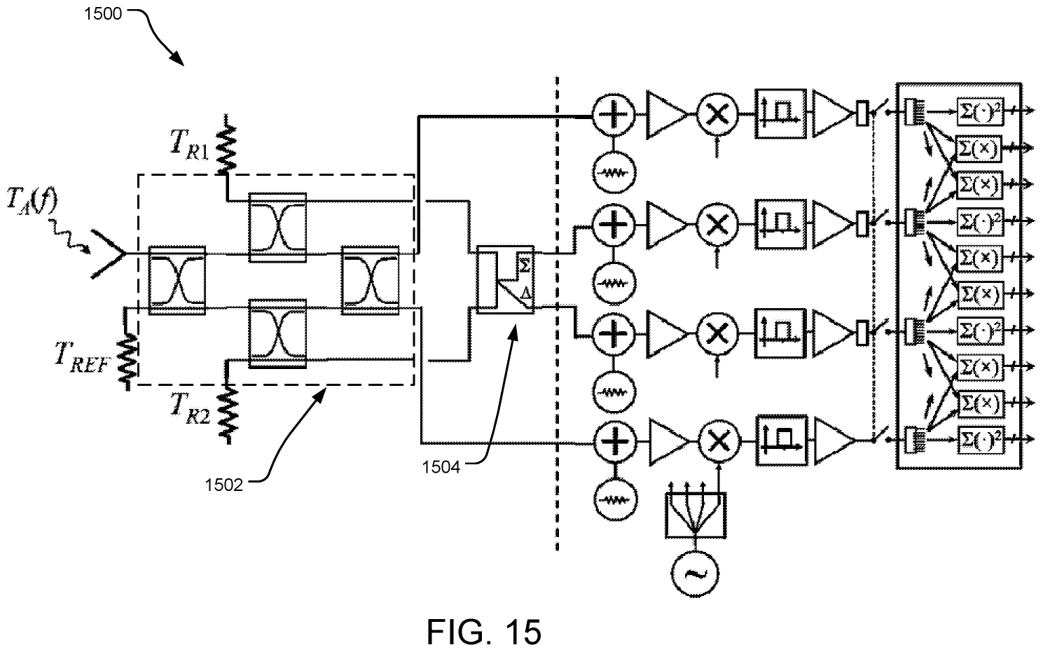

FIG. 15 illustrates a 4-path 4QQQQS digital correlating radiometer 1500. Specifically, the 4-path 4QQQQS digital correlating radiometer 1500 includes a transmission combiner including four quadrature (Q) couplers 1502 and one sum-difference(S) coupler 1504. The 4-path 4QQQQS digital correlating radiometer 1500 is fully radiometric efficient (η_{rad}=100%). This is one possible implementation adding reference noise signals in quadrature phase to the sum-difference antenna signals. Inversion for T_{A} is based on the phase angles of 6 correlation counts. This implementation also allows inversion of gains and receiver temperatures using correlators magnitudes, as well as phase angles, for improved accuracy. Given that the 4-path 4QQQQS digital correlating radiometer 1500 uses 4 paths, it provides 4*(4−1)/2=12 total measurements, or six complex measurements, thus significantly providing more measurements than the number of unknowns that need to be learned to provide radiometer calibration.

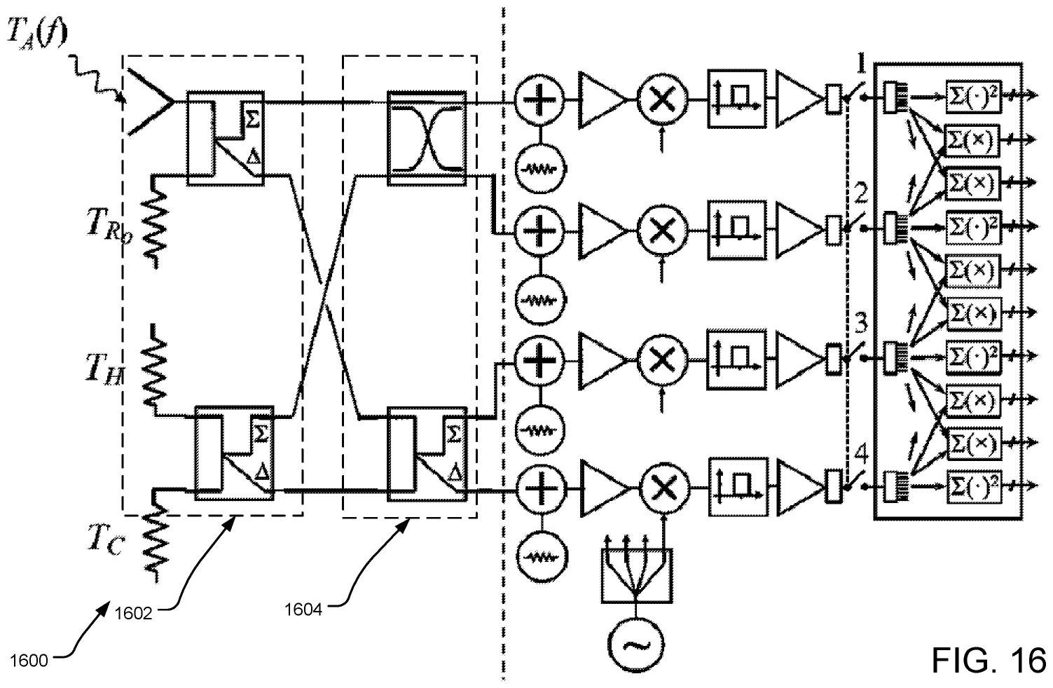

FIG. 16 illustrates a 4-path 4SSQS digital correlating radiometer 1600. The 4-path 4SSQS digital correlating radiometer 1600 includes two sum-difference couplers 1602 receiving the input temperature signals followed by a combination 1604 of a sum-difference coupler and a quadrature coupler. The 4-path 4SSQS digital correlating radiometer 1600 is fully signal efficient (η_{rad}=100%) and it is another implementation adding in signals in quadrature phase to sum-difference signals. Here, inversion of T_{A}, path gains, path phase differences, and receiver temperatures are demonstrated numerically.

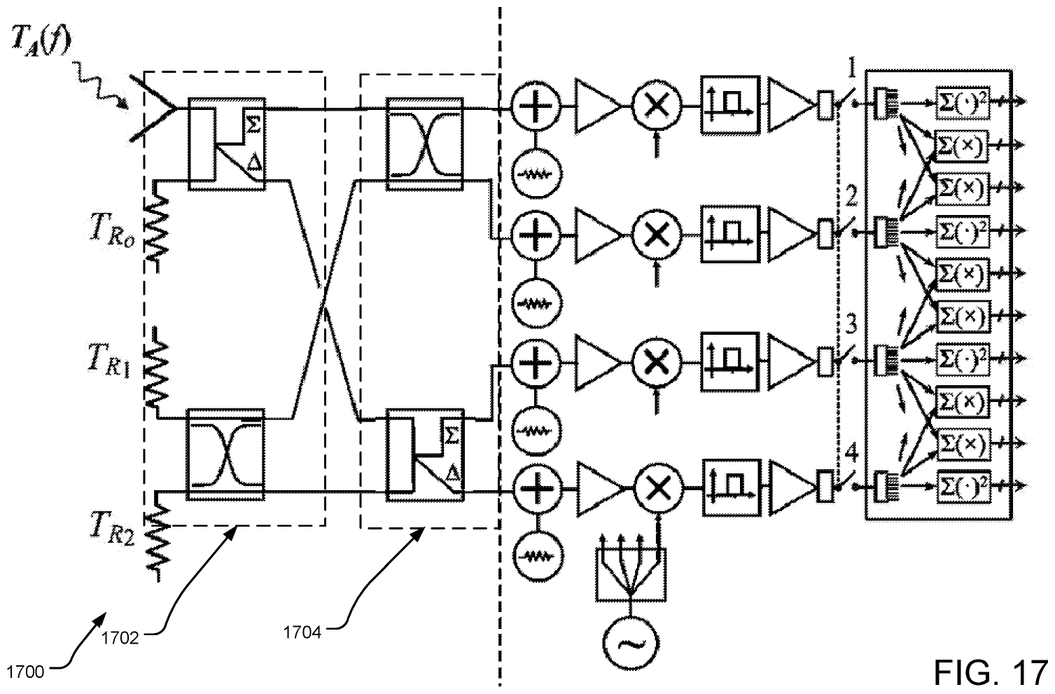

FIG. 17 illustrates a 4-path 4SQQS digital correlating radiometer 1700. The 4-path 4SQQS digital correlating radiometer 1700 includes a combination 1702 of a sum-difference coupler and a quadrature coupler receiving the input temperature signals followed by a reversed combination 1704 of a sum-difference coupler and a quadrature coupler. The 4-path 4SQQS digital correlating radiometer 1700 provides rank deficient correlator equations that provide no possible inversion using cross-correlator phases, but a possible inversion using cross-correlator magnitudes.

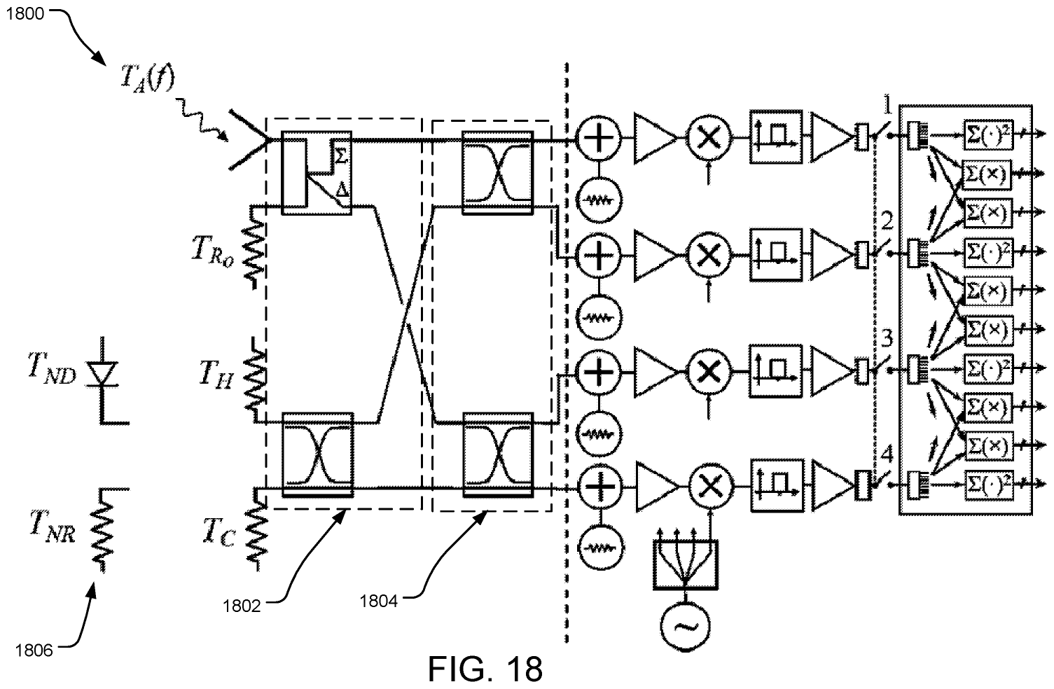

FIG. 18 illustrates a 4-path 4SQQQ digital correlating radiometer 1800. The 4-path 4SQQQ digital correlating radiometer 1800 includes a combination of 1802 of a sum-difference coupler and a quadrature coupler receiving the input temperature signals followed by a combination 1804 of two quadrature couplers. The 4-path 4SQQQ digital correlating radiometer 1800 is fully radiometric efficient providing 6 complex nonlinear cross-correlation equations in 4+3+1=8 unknowns, thus being 1.5× overdetermined. Specifically, the combiner provides a count coherency matrix with off-diagonal entries that are generally complex and permit both real and imaginary cross-correlation counts to be used in either phase only or magnitude and phase inversion. Here, either noise diode or thermal references can be used. The 4-path 4SQQQ digital correlating radiometer 1800 allows substituting T_{H} and T_{C} for noise diode and references TND and TNR 1806.

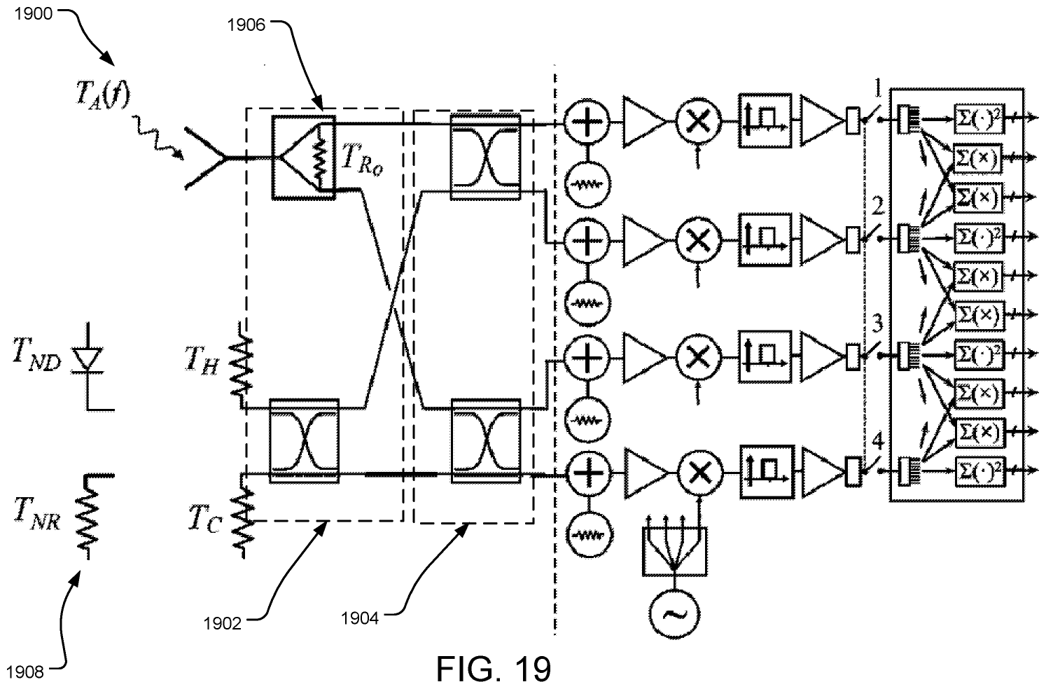

FIG. 19 illustrates a 4-path 4SQQQ implementation 1900 readily suitable for L-Band (1-2 GHZ). The 4-path 4SQQQ implementation 1900 includes a combination of 1902 of a sum-difference coupler and a quadrature coupler receiving the input temperature signals followed by a combination 1904 of two quadrature couplers. The 4-path 4SQQQ implementation 1900 uses a Wilkinson coupler for the sum-difference coupler 1906. This Wilkinson coupler could also be integrated into the antenna. The 4-path 4SQQQ implementation 1900 also allows substituting T_{H} and T_{C} for noise diode and references TND and TNR 1908.

In one implementation, a complex cross-correlator 1910 provides multipath cross-correlation radiometry (MXCR) using a subspace contraction and consolidation method as described below. Specifically, the complex cross-correlator 110 provides MXCR wherein a coherency matrix for the received signals that is measured by the plurality of complex correlators is related to the input signal power spectra (or, equivalently, the input signal noise temperature spectra) along with the reference temperature spectra and unknown gain, phase shift, and noise temperature spectra for each receiver path. For example, for the 4-path 4SQQQ implementation 1900, including a transmission network comprising 1902, 1904, and 1906, the relationship at each spectral frequency may be described by the measured coherence matrix c below:

$$\overline{\overline{c}} = [ \begin{matrix}{c}_{11} & {c}_{12} & {c}_{13} & {c}_{14} \\ {c}_{21} & {c}_{22} & {c}_{23} & {c}_{24} \\ {c}_{31} & {c}_{32} & {c}_{33} & {c}_{34} \\ {c}_{41} & {c}_{42} & {c}_{43} & {c}_{44}\end{matrix} ] = {\overline{\overline{G}}}_{υ} ( \overline{\overline{T}} {\overline{\overline{J}}}_{I} {\overline{\overline{T}}}^{†} + {\overline{\overline{J}}}_{R} ) {\overline{\overline{G}}}_{υ}^{†}$$

Here c is the measured coherency matrix (with the double overbars indicating a matrix of numbers), Gᵥ is the complex magnitude and phase path gain matrix and is diagonal in form, T is the transmission network matrix describing the signal transmission behavior the transmission network [1902, 1904, and 1906 in FIG. 19], J_{I} is the diagonal input signal coherency matrix containing the input and reference signal temperatures along its diagonal, and JR is the diagonal receiver noise coherency matrix containing the receiver noise temperatures along its diagonal.

The matrix relationship discussed herein is invertible to determine the input signal power (or, equivalently temperature) spectra by forming specific ratios of products of off-diagonal coherency matrix elements that result in cancellation of the unknown path gains and phases. Since only off-diagonal coherency matrix elements are used there is no involvement of the receiver noise temperatures in matrix JR. To find the possible ratios of products the matrix entries are first reshaped to form a one-dimensional vector, then the logarithm of each coherency matrix element is taken, and finally a series of subspace projection matrices are subsequently applied to reject any and all unknown receiver gain, phase, and noise temperature terms. For example, for the 4-path radiometer in FIG. 19 the following three ratios of coherencies the reject the unknown receiver gain, phase, and noise temperatures have been found using this method.

$$\frac{{c}_{31} {c}_{42}}{{c}_{41} {c}_{32}} \frac{{c}_{41} {c}_{23}}{{c}_{21} {c}_{43}} \frac{{c}_{31} {c}_{24}}{{c}_{21} {c}_{34}}$$

Furthermore, the transmission network comprising 1902, 1904, and 1906 may be designed so that any or all of these three fundamental ratios of products can be related to the input signal powers through invertible expressions that are either linear or quadratic in form and thus do not require knowledge of the receiver path gains, phases, or noise spectra. In this manner fluctuating or otherwise unknown variations in the receiver gains, phases, or receiver temperatures caused by (for example) temperature, aging, manufacturing tolerances, vibrations, humidity, supply voltage variations, radio frequency interference causing gain compression, transmission line or cable flexure or strain, digital sampling noise, digital sampling converter range variations, local oscillator power variations, or other random effects on the receiver paths are rejected in the input signal power detection process. The detection hardware and signal processing method can be developed using subspace contraction and consolidation or can be posited using the above gain-cancelled coherency matrix element product ratios.

Furthermore, the MXCR can also be used in a feedback scheme to inject controlled signal waveforms of known power level comparable to either the desirable or undesirable (e.g., interfering) signals at the input ports back into either the input port or reference port. In this manner the MXCR detection method can null out interfering signals of statistically persistent form. Examples of such undesirable interfering signals include continuous or pulsed sinusoids which can be detected using either second-order analysis (e.g., statistical power estimation) and/or fourth-order statistical analysis (e.g., statistical kurtosis estimation). Other such signals include narrowband or broadband modulated signals which also can be detected using power or kurtosis estimation. Either analog or digitally generated versions of these signals can be generated or synthesized and coupled back into the input or reference signal ports to serve to cancel out the interfering signal and/or maintain the functionality of the MXCR detection method by keeping the digitized signals within the range of accuracy of the analog or digital signal sampling method used. Information on the presence of such desirable or undesirable signals can also be used to adjust the receiver path gains, phases, or digital sampling sensitivities to ensure optimal function of the MXCR detection method. Such changes can be made dynamically as the input signal is statistically analyzed and form a capability analogous to the “automatic gain controls” that are used in stabilizing the response of radio detection systems.

Once the MXCR method is implemented and provides an estimate of the input signal power or temperature spectra this information can be used again in the above matrix equation to estimate the individual instantaneous receiver path gains, phases, and receiver noise temperature spectra. In this manner the MXCR method can be used to characterize receivers according to the gain, phase, and noise behavior with respect to changes in any of temperature, age, manufacturing tolerance, vibration, humidity, supply voltage variation, radio frequency interference causing gain compression, transmission line or cable flexure or strain, digital sampling precision, digital sampling converter range, local oscillator power variation, or other random effects. The receivers that can be used and/or characterized using MXCR span the spectrum from audio or lower frequencies up through the terahertz range of the electromagnetic spectrum.

The 4-path 4SQQQ implementation 1900 is fully radiometric efficient providing 6 complex nonlinear cross-correlation equations in 4+3+1-8 unknowns, thus being 1.5× overdetermined. The illustrated implementation is for L-Band (1-2 GHz) using TI 4-channel coherent ADC sampler operating at 125 MSps and 45 MHz IF bandwidth. In other implementations, software defined radios (SDRs). Inexpensive SRDs such as the “RTLSDR” with low bandwidths as small as 2 MHz may also be used. Here reference temperature is provided by the Wilkinson divider resistor TRO. Input temperature references may be either an attenuated noise diode or thermal references 1908. In one implementation, the input temperature references 1908 may be one of thermal terminations, noise diodes, cold amplifier inputs (including FET amplifiers), pseudorandom digitally generated noise sources, and sinusoidal reference signal sources.

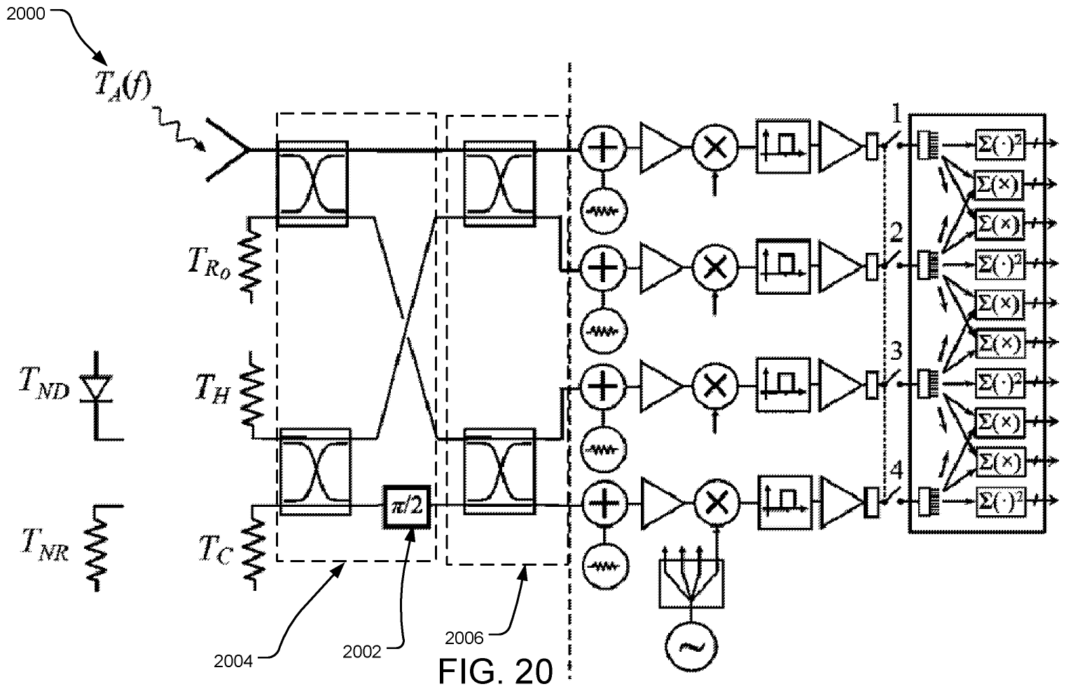

FIG. 20 illustrates a 4-Path 4QQDQQ digital correlating radiometer 2000. The 4-Path 4QQDQQ digital correlating radiometer 2000 uses four quad couplers with a 90 degree phase shift 2002 between the output of the first two quad couplers 2004 and the second two quad couplers 2006. The combiner disclosed herein permits use of matched quadrature hybrid couplers along with 90° phase shift to effectively convert the lower left coupler into 2-A coupler for proper phasing. One advantage of the 4-Path 4QQDQQ digital correlating radiometer 2000 is in component matching for transmission T-matrix symmetry.

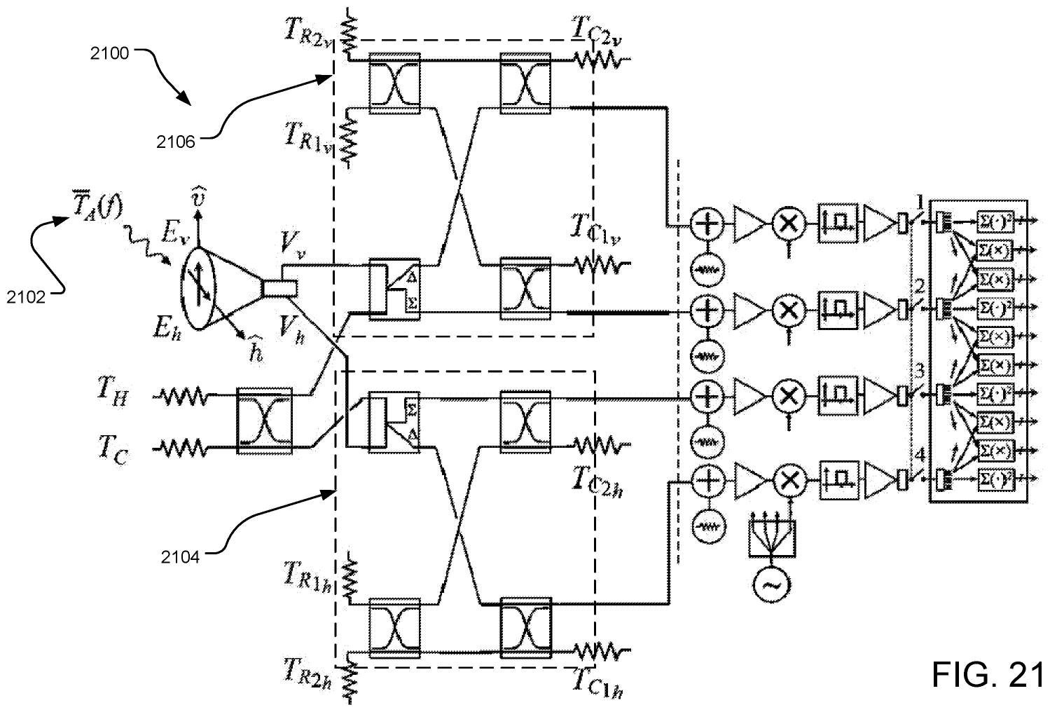

FIG. 21 illustrates a 4-Path 2-4SQQQ digital correlating polarimeter 2100. The 4-Path 2-4SQQQ digital correlating polarimeter 2100 allows measuring radiation intensities in vertical and horizontal polarization and measuring correlation between the electric field intensities in vertical and horizontal polarization. Here the input is a vector of Stokes' parameters T_{A}(f) 2102, namely T_{A} vertical, T_{A} horizontal, T_{U} and T_{V} (the real and imaginary parts of the cross correlation of the electrical fields Eᵥ and Eₕ). The 4-Path 2-4SQQQ digital correlating polarimeter 2100 has a pair of QSQQ transmission combiners 2104 and 2106 generating four receiver paths.

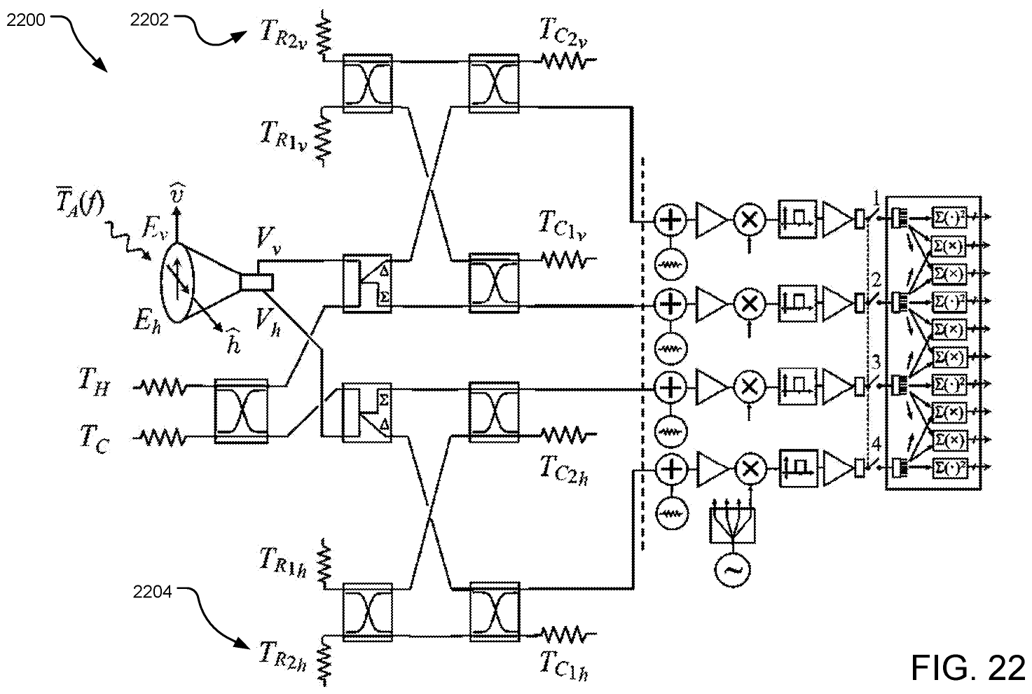

FIG. 22 illustrates an alternate implementation of 4-Path 2-4SQQQ digital correlating polarimeter 2200. Specifically, the 4-Path 2-4SQQQ digital correlating polarimeter 2200 uses noise diodes T_{R2v} 2202 and T_{R2h} 2204. The 4-Path 2-4SQQQ digital correlating polarimeter 2200 provides radiometric efficiency η_{rad} of 1−C². Here the path phase delay differences can be determined by turning off the T_{Rxa} noise differences.

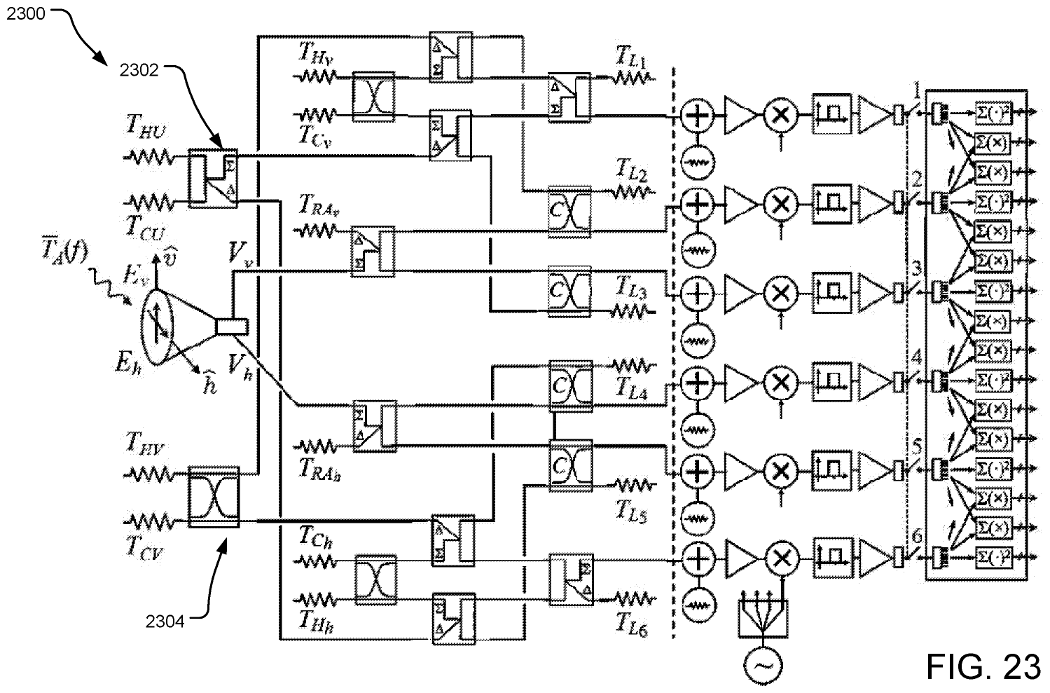

FIG. 23 illustrates a 6-path phase-calibrating digital correlating polarimeter 2300. The 6-path phase-calibrating digital correlating polarimeter 2300 includes a nearly radiometric efficient 24-port combiner that generates six complex linear cross-correlation equations, thus generating 6*(6−1)/2 or 15 measurements permitting solving for 15 unknowns. The 6-path phase-calibrating digital correlating polarimeter 2300 uses hot references such as from noise diodes for high radiometric efficiency. Here the U and V represent the third and fourth Stokes' parameters, with T_{HU} and T_{CU} being hot and cold third Stokes' reference temperatures input to a sum-difference coupler 2302 and T_{HV} and T_{CV} being hot and cold fourth Stokes' reference temperatures input to a quadrature coupler 2304.

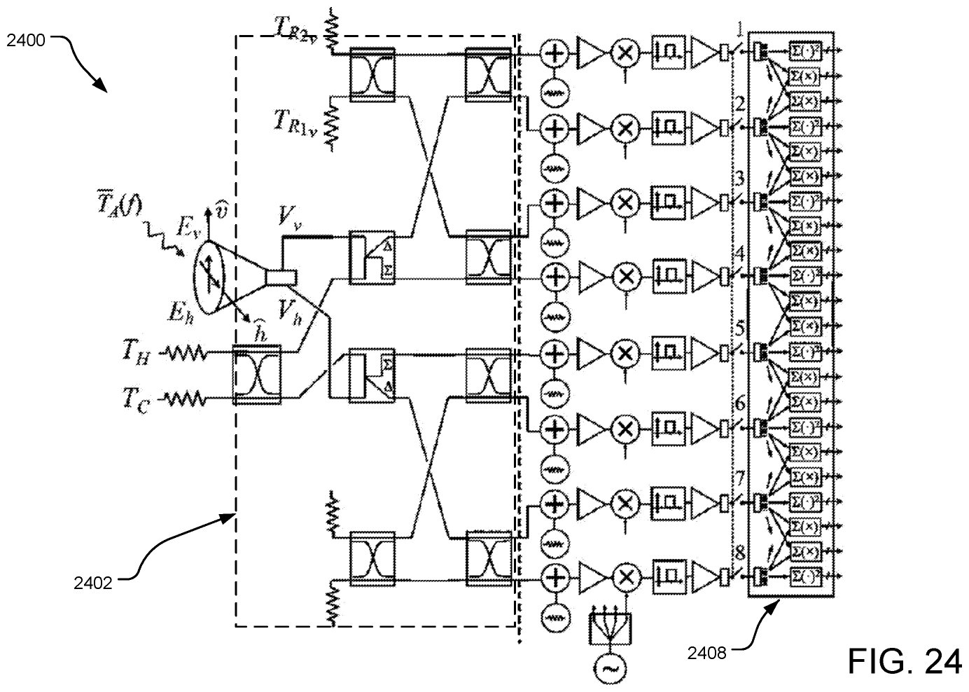

FIG. 24 illustrates an 8-path phase-calibrating digital correlating polarimeter 2400. The 8-path phase-calibrating digital correlating polarimeter 2400 provides a rank sufficient phase design matrix that separates T_{U} and T_{V} without need to know path phases. The combiner 2408 provides off-diagonal coherence count values that are generally complex but do not permit full Stokes' vector inversion. The 8-path phase-calibrating digital correlating polarimeter 2500 requires a total of 28 complex cross-correlating accumulators 2408. These cross-correlating accumulators can be implemented in, for example, Field Programmable Gate Array (FPGA) logic devices.

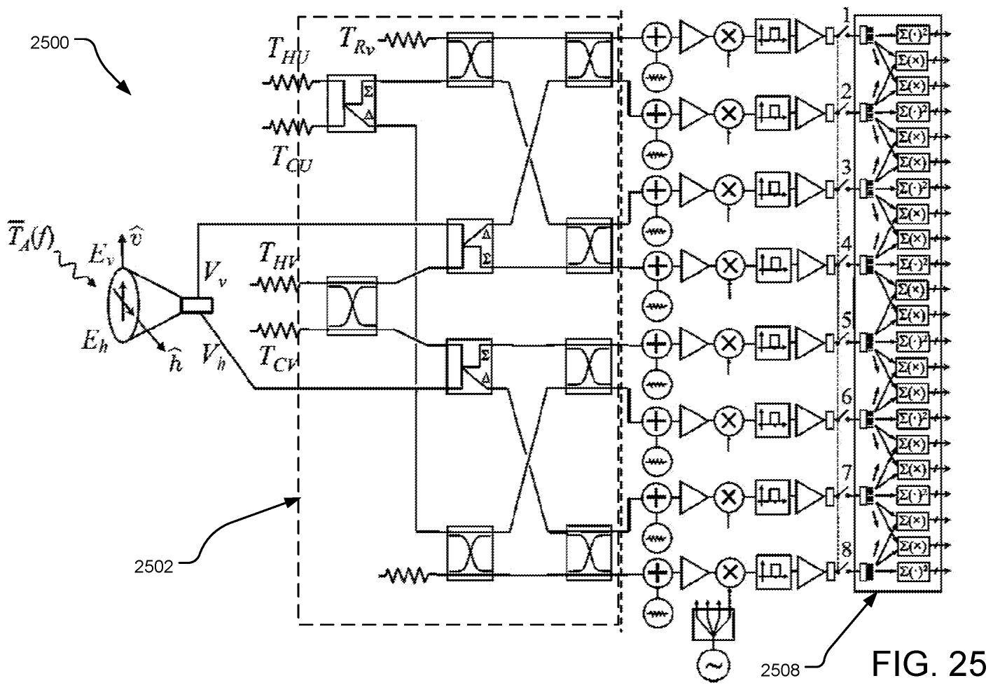

FIG. 25 illustrates an alternative 8-path phase-calibrating digital correlating polarimeter 2500. The 8-path phase-calibrating digital correlating polarimeter 2500 includes a combiner 2502 that provides off-diagonal coherence count values that are generally complex and permit full Stokes vector inversion with η_{rad}=100% (full) signal efficiency using either thermal noise sources or noise diodes. The 8-path phase-calibrating digital correlating polarimeter 2500 requires a total of 28 complex cross-correlating accumulators in the cross-correlator 2508.

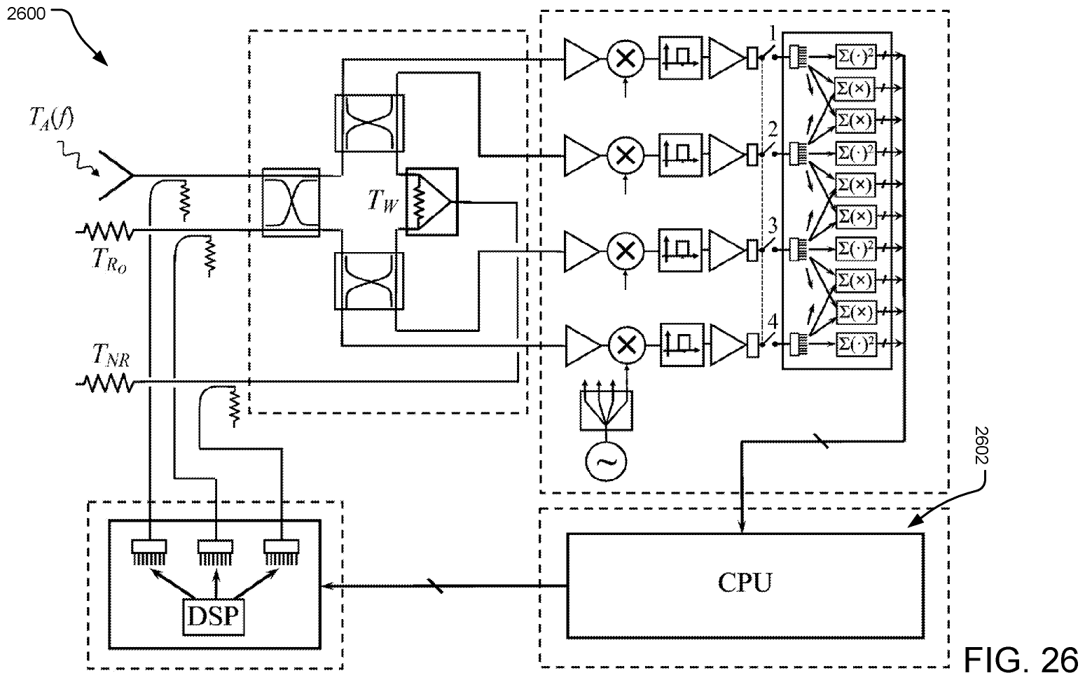

FIG. 26 illustrates an alternative 8-path phase-calibrating digital correlating polarimeter 2600. Specifically, the 8-path phase-calibrating digital correlating polarimeter 2600 includes an FFT spectral processor (implemented on a CPU 2602) that could be used in the feedback process.

FIG. 27 illustrates a computing device 2700 that may be used for implementing the features and operations of the described technology. The computing device 2700 may embody a remote-control device or a physical controlled device and is an example network-connected and/or network-capable device and may be a client device, such as a laptop, mobile device, desktop, tablet; a server/cloud device; an internet-of-things device; an electronic accessory; or another electronic device. The computing device 2700 includes one or more processor(s) 2702 and a memory 2704. The memory 2704 generally includes both volatile memory (e.g., RAM) and nonvolatile memory (e.g., flash memory). An operating system 2710 resides in the memory 2704 and is executed by the processor(s) 2702. The host computing device 202 may be an implementation of computing device 2700.

In an example computing device 2700, as shown in FIG. 27, one or more modules or segments, such as applications 2750, APIs, and/or a malware mitigator (e.g., in implementations in which the malware mitigator 208 is at least partially software-based) are loaded into the operating system 2710 on the memory 2704 and/or storage 2720 and executed by processor(s) 2702. The storage 2720 may include one or more tangible storage media devices and may store snapshots, vulnerable data, suspicious data, malware, cached data, data hashes, predefined suspicious data hashes, predefined parameter thresholds, predefined ranges of parameter values, predefined numbers of snapshots, predefined frequencies of operations, data corruption conditions, metadata, locally and globally unique identifiers, requests, responses, and other data and be local to the computing device 2700 or may be remote and communicatively connected to the computing device 2700. The storage 2720 may be an implementation of one or more of the storage devices 222A-C. In implementations, the storage device may include a storage controller and/or a malware mitigator (e.g., an implementation of the storage controller 210 and/or the malware mitigator 208).

The computing device 2700 includes a power supply 2716, which is powered by one or more batteries or other power sources and which provides power to other components of the computing device 2700. The power supply 2716 may also be connected to an external power source that overrides or recharges the built-in batteries or other power sources.

The computing device 2700 may include one or more communication transceivers 2730, which may be connected to one or more antenna(s) 2732 to provide network connectivity (e.g., mobile phone network, Wi-Fi®, Bluetooth®) to one or more other servers and/or client devices (e.g., mobile devices, desktop computers, or laptop computers). The computing device 2700 may further include a communications interface 2736 (e.g., a network adapter), which is a type of computing device. The computing device 2700 may use the communications interface 2736 and any other types of computing devices for establishing connections over a wide-area network (WAN) or local-area network (LAN). It should be appreciated that the network connections shown are examples and that other computing devices and means for establishing a communications link between the computing device 2700 and other devices may be used.

The computing device 2700 may include one or more input devices 2734 such that a user may enter commands and information (e.g., a keyboard or mouse). These and other input devices may be coupled to the server by one or more interfaces 2738, such as a serial port interface, parallel port, or universal serial bus (USB). The one or more interfaces may be implementations of the communication interface 206. The computing device 2700 may further include a display 2722, such as a touch screen display.

The computing device 2700 may include a variety of tangible processor-readable storage media and intangible processor-readable communication signals. Tangible processor-readable storage can be embodied by any available media that can be accessed by the computing device 2700 and includes both volatile and nonvolatile storage media, removable and non-removable storage media. Tangible processor-readable storage media excludes communications signals (e.g., signals per se) and includes volatile and nonvolatile, removable and non-removable storage media implemented in any method or technology for storage of information such as processor-readable instructions, data structures, program modules, or other data. Tangible processor-readable storage media includes, but is not limited to, RAM, ROM, EEPROM, flash memory or other memory technology, CDROM, digital versatile disks (DVD) or other optical disk storage, magnetic cassettes, magnetic tape, magnetic disk storage, or other magnetic storage devices, or any other tangible medium which can be used to store the desired information and which can be accessed by the computing device 2700. In contrast to tangible processor-readable storage media, intangible processor-readable communication signals may embody processor-readable instructions, data structures, program modules, or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include signals traveling through wired media such as a wired network or direct-wired connection, and wireless media such as acoustic, RF, infrared, and other wireless media.

Various software components described herein are executable by one or more processors, which may include logic machines configured to execute hardware or firmware instructions. For example, the processors may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

Aspects of processors and storage may be integrated together into one or more hardware logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of a remote-control device and/or a physically controlled device implemented to perform a particular function. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

It will be appreciated that a “service,” as used herein, is an application program executable across one or multiple user sessions. A service may be available to one or more system components, programs, and/or other services. In some implementations, a service may run on one or more server computing devices.

The logical operations making up implementations of the technology described herein may be referred to variously as operations, steps, objects, or modules. Furthermore, it should be understood that logical operations may be performed in any order, adding, or omitting operations as desired, regardless of whether operations are labeled or identified as optional, unless explicitly claimed otherwise or a specific order is inherently necessitated by the claim language.

One or more implementations disclosed above provide multipath cross correlation radiometers. Specifically, the radiometers disclosed above use combiners with various combinations of sum-difference couplers and quadrature couplers receiving input and reference temperature signals. The outputs from the combiners are input to various configurations of N-path coherent radio receiver arrays. The output from the N-path coherent radio receiver array is input to various configurations of cross-correlators. The outputs from the cross-correlators are input to a computer wherein one or more computer algorithms are used to process the cross-correlation output signals.

Alternative implementations of the multipath cross correlation radiometers and their benefits are also disclosed in the attached documents entitled (a) Appendix A-Phase Reference Correlation Radiometry and (b) Appendix B-Multipath Cross-Correlation Radiometry, each of which are incorporated herein by reference.

What is claimed is:

1. A radiometer system, comprising:
an N-path transmission combiner including one or more sum-difference couplers and one or more quadrature couplers to generate N-path output signals including one or more sum output signals, difference output signals, and quadrature injected noise reference output signals; and
an N-path radio receiver array configured to couple the one or more sum output signals, the difference output signals, and the quadrature injected noise reference output signals into a complex cross-correlator,
wherein the complex cross-correlator is configured to process the one or more sum output signals, the difference output signals, and the quadrature injected noise reference output signals to generate a plurality of calibration outputs to be interpreted by a computer based algorithm to determine calibration parameters of the radiometer system.

2. The radiometer system of claim 1, wherein the complex cross-correlator is configured to generate the calibration outputs based on complex correlation between an in-phase part I and a quadrature phase part Q.

3. The radiometer system of claim 1, wherein the N-path transmission combiner is a 2-path transmission combiner comprising:
a sum-difference coupler configured to receive in an input antenna T_{A}(f) signal and a reference signal T_{REF} and generate a sum output signal and a difference output signal, and
a quadrature coupler configured to couple in a noise reference TNR signal and a noise diode TND signal to generate a quadrature injected noise reference output signal.

4. The radiometer system of claim 3 wherein the sum-difference coupler is implemented using a Wilkinson divider.

5. The radiometer system of claim 1, wherein the N-path transmission combiner is a 3-path transmission combiner comprising:
a sum-difference coupler receiving T_{A} and T_{RA} and generating output signals that are input into two quadrature couplers; and
a quadrature coupler receiving T_{C} and T_{H} and generating output signals that are input into two sum-difference couplers.

6. The radiometer system of claim 5, wherein the outputs from the two sum-difference couplers are input into another sum-difference coupler.

7. The radiometer system of claim 1, wherein the transmission combiner is a 4-path transmission combiner including four quadrature (Q) couplers and one sum-difference(S) coupler.

8. The radiometer system of claim 1, wherein the transmission combiner is a 4-path transmission combiner including three sum-difference(S) couplers and one quadrature coupler (Q).

9. The radiometer system of claim 1, wherein the transmission combiner is a 4-path transmission combiner including two sum-difference(S) couplers and two quadrature couplers (Q).

10. The radiometer system of claim 1, wherein the transmission combiner is a 4-path transmission combiner including one sum-difference(S) coupler and three quadrature couplers (Q).

11. The radiometer system of claim 1, wherein the transmission combiner is a 4-path transmission combiner including one sum-difference(S) coupler and three quadrature couplers (Q), wherein the sum-difference(S) coupler is implemented using a Wilkinson coupler.

12. The radiometer system of claim 1, wherein the transmission combiner is a 4-path transmission combiner including four quadrature couplers (Q) and further comprising a 90° phase shifter between the first two of the four quadrature couplers (Q) and the last two of the four quadrature couplers (Q).

13. The radiometer system of claim 1, wherein the transmission combiner is a 6-path transmission combiner.

14. The radiometer system of claim 1, wherein the transmission combiner is an 8-path transmission combiner.

15. The radiometer system of claim 1, wherein the complex cross-correlator may be implemented using at least one of (a) an analog-to-digital sampling and digital cross-correlation and (b) an analog multiplication or squaring and analog cross-correlation.

16. The radiometer system of claim 1, wherein the complex cross-correlator may be implemented using either analog-to-digital sampling and digital cross-correlation or analog multiplication or squaring and analog cross-correlation.

17. A radiometer system, comprising:
an N-path transmission combiner including one or more sum-difference couplers and one or more quadrature couplers to generate N-path output signals including one or more sum output signals, difference output signals, and quadrature injected noise reference output signals;
an N-path radio receiver array configured to couple the one or more sum output signals, the difference output signals, and the quadrature injected noise reference output signals into a complex cross-correlator,
wherein the complex cross-correlator is configured to process the one or more sum output signals, the difference output signals, and the quadrature injected noise reference output signals to generate a plurality of calibration outputs to be interpreted by a computer based algorithm to determine calibration parameters of the radiometer system; and
wherein the N-path transmission combiner is a 3-path transmission combiner comprising a sum-difference coupler receiving T_{A} and T_{RA} and generating output signals that are input into two quadrature couplers and a quadrature coupler receiving T_{C} and T_{H} and generating output signals that are input into two sum-difference couplers.

18. The radiometer system of claim 17, wherein the outputs from the two sum-difference couplers are input into another sum-difference coupler.

19. The radiometer system of claim 17, wherein the transmission combiner is at least one of a 6-path transmission combiner and an 8-path transmission combiner.

20. The radiometer system of claim 17, wherein the transmission combiner is a 4-path transmission combiner including four quadrature couplers (Q) and further comprising a 90° phase shifter between the first two of the four quadrature couplers (Q) and the last two of the four quadrature couplers (Q).
